(19) United States
(12) Patent Application Publication
(10) Pub. No.: US 2026/0165182 A1
(43) Pub. Date: Jun. 11, 2026

(54) PRE-CLEAN AND DRY SAM APPLICATION TO IMPROVE HYBRID BONDING RELIABILITY AND ELECTRICAL PERFORMANCE

(71) Applicant: Applied Materials, Inc., Santa Clara, CA (US)

(72) Inventor: Zheng Da Clinton GOH, Singapore (SG)

(21) Appl. No.: 18/971,951

(22) Filed: Dec. 6, 2024

(51) Int. Cl. H01L 23/00

(52) U.S. Cl. CPC H10W 72/90; H10W 72/019; H10W 72/01953; H10W 72/01961; H10W 72/01971; H10W 72/923; H10W 72/934; H10W 72/952; H10W 72/953; H10W 95/00

(57) ABSTRACT

Embodiments of the present invention generally relate to a system and methods for processing substrates, in particular, forming a capping layer on pads to prevent oxidation during bonding. In at least one embodiment, a method is provided. The method includes, providing patterned device structures including a dielectric layer disposed over a substrate, the dielectric layer including a plurality of interconnect structures etched therein, an interconnect material disposed within the plurality of interconnect structures forming a plurality of pads within the plurality of interconnect structures of the patterned device structures. The method further includes removing a contaminant from the patterned device structures using a plasms treatment process to expose a surface of the pads within the interconnect structures of the patterned device structures, and selectively depositing a self-assembled monolayer (SAM) capping layer on the exposed pads within the interconnect structures of the patterned device structures.

### BACKGROUND

### Field

Embodiments of the present disclosure generally relate to a system and methods for processing substrates, in particular, forming a capping layer on pads to prevent oxidation during bonding.

### Description of the Related Art

Substrate processing units may perform chemical mechanical polishing (CMP), which is commonly used in the manufacturing of high-density integrated circuits to planarize or polish a layer of material deposited on a substrate. In a typical CMP process, a substrate is retained in a carrier head that presses the backside of the substrate towards a rotating polishing pad in the presence of a polishing fluid. Material is removed across the material layer surface of the substrate in contact with the polishing pad through a combination of chemical and mechanical activity which is provided by the polishing fluid and a relative motion of the substrate and the polishing pad. Typically, after one or more CMP processes are completed, a polished substrate is further processed by use of one or more post-CMP substrate processing operations in a CMP processing system. For example, the polished substrate may be further processed using one or more cleaning operations in a cleaning unit. Various cleaning operations may be performed in a cleaning unit having multiple cleaning stations, i.e., cleaning chambers. Once the post-CMP operations are complete, the substrate can be removed from a CMP processing system and then delivered to the next device manufacturing system, such as a lithography, etch, or deposition system.

In some packaging applications, after the CMP process, the polished substrate is bonded to a corresponding substrate. In one or more types of bonding, metal pads formed in interconnect structures of correspond substrates are aligned. However due to the CMP process there is dishing present on the metal pads. Therefore, after the substrates are bonding a post-bonding anneal process is performed to cause the pads to expand, contact, and then diffuse into one another. However, the surfaces of the metal pads, when exposed to air for a period of time and during the annealing process, will form an oxide layer that will affect the circuit resistance of the bonded metal pads.

Therefore, there is a need in the art for a method of forming bonded pads during a device packaging process that solves the problems described above.

### SUMMARY

Embodiments of the present disclosure generally relate to a system and method for processing substrates, in particular, forming a capping layer on pads to prevent oxidation during bonding.

In at least one embodiment, a method is provided. The method includes, providing patterned device structures including a dielectric layer disposed over a substrate, the dielectric layer including a plurality of interconnect structures etched therein, an interconnect material disposed within the plurality of interconnect structures forming a plurality of pads within the plurality of interconnect structures of the patterned device structures. The method further includes removing a contaminant from the patterned device structures using a plasms treatment process to expose a surface of the pads within the interconnect structures of the patterned device structures, and selectively depositing a self-assembled monolayer (SAM) capping layer on the exposed pads within the interconnect structures of the patterned device structures.

In at least one embodiment, a patterned device structure is provided. The patterned device structure includes a dielectric layer disposed over a substrate, the dielectric layer including a plurality of interconnect structures etched therein. An interconnect material is disposed within the plurality of interconnect structures forming a plurality of pads within the plurality of interconnect structures, and a self-assembled monolayer (SAM) capping layer disposed on at least one pad of the plurality of pads.

In at least one embodiment, a method is provided. The method includes, providing two or more patterned device structures including an interconnect material disposed over a dielectric layer disposed over a substrate. The dielectric layer including a plurality of interconnect structures etched therein, where the interconnect material fills the plurality of interconnect structures, and is disposed over the plurality of interconnect structures and a field region of the dielectric layer. A chemical mechanical polishing (CMP) process is preformed to remove portions of the interconnect material disposed on the field region of the dielectric layer and expos a plurality of pads within the plurality of interconnect structures of the two or more patterned device structures. The method further includes, exposing the plurality of pads of the two or more patterned device structures to atmosphere, exposing the plurality of pads to a plasma treatment process, and selectively depositing a self-assembled monolayer (SAM) capping layer on the exposed pads within the interconnect structures of the two or more patterned device structures after exposing the plurality of pads to a plasma treatment process. The method further includes, bonding corresponding patterned device structures of the two or more patterned device structures to each other and annealing the bonded corresponding patterned device structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1E illustrate schematic diagrams of a packaged device during bonding according to one or more embodiments.

FIG. 2 illustrates operations for a method for hybrid bonding according to one or more embodiments.

FIG. 3 illustrates a schematic plan view of a cluster tool according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a system and method for processing substrates. More specifically, embodiments described herein relate to forming a capping layer on metal containing pads to prevent oxidation during a bonding process sequence. It has been discovered that self-assembling monolayers (SAM) having a high selectivity to copper can be deposited as capping layers on copper pads using the methods described herein, to prevent oxidation. In at least some embodiments, the SAM capping layer is removed during a pre-bonding plasma activation step, at the same rate that the surrounding dielectric is activated. Methods disclosed herein generally include a sequential pre-cleaning step to remove metal oxide and an atomic layer deposition (ALD) step to deposit the SAM capping layer, that are performed without an air-break.

Chemical mechanical polishing (CMP) is a process that can be used multiple times in a packaging process sequence. In most instances, CMP is used to planarize a layer of a packaging substrate and/or die and create a smooth surface. In one embodiment, CMP is used during a bonding process sequence between heterogeneous or homogenous dies and/or wafers. For example, during a hybrid bonding process a die may include a dielectric layer formed over a substrate. The substrate may also include multiple layers of dielectric materials and metal wiring known as back-end-of-the line (BEOL) layers. In one embodiment, a dielectric layer can be the last layer of BEOL, or an additional layer deposited specifically for hybrid bonding. Interconnect structures can be etched and arranged into the dielectric layer and form bonding surfaces between the interconnect structures. The bonding surfaces are positioned so that interconnect structures of opposing dies can be mated to one other.

In one or more embodiments, the etched interconnect structures are filled with a conductive material such that the opposing interconnect structures of opposing dies can be mated and form interconnects. The conductive material is deposited over the dielectric layer, fills the interconnect structures, and covers the dielectric layer. Then a CMP process is performed to remove a portion of the conductive material from bonding surfaces to re-expose them and form/expose electrically conductive pads (herein described as “pads”) in the interconnect structures. After the CMP process, the substrate undergoes cleaning and other bonding processes. To cause the pads to mate, a post-bond annealing process is used to cause the conductive material on each die to expand, contact, and diffuse into one another. However, due to limited thermal budgets of most packaging applications, current post-bonding annealing processes are performed at too high of a temperature to assure that a good electrical contact can be formed between the oxidized surface(s) of the pads due their exposure to the ambient environment. Typical post bonding annealing temperatures are from about 350° C. to about 400° C. Embodiments described herein disclose a process and apparatus for depositing a capping layer on the pads to reduce the temperature required for post-bond annealing.

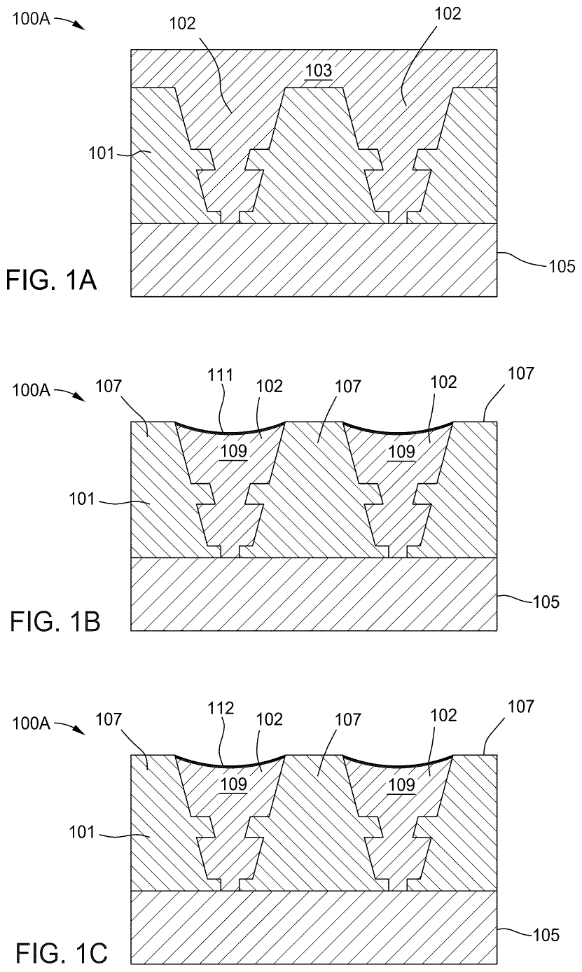

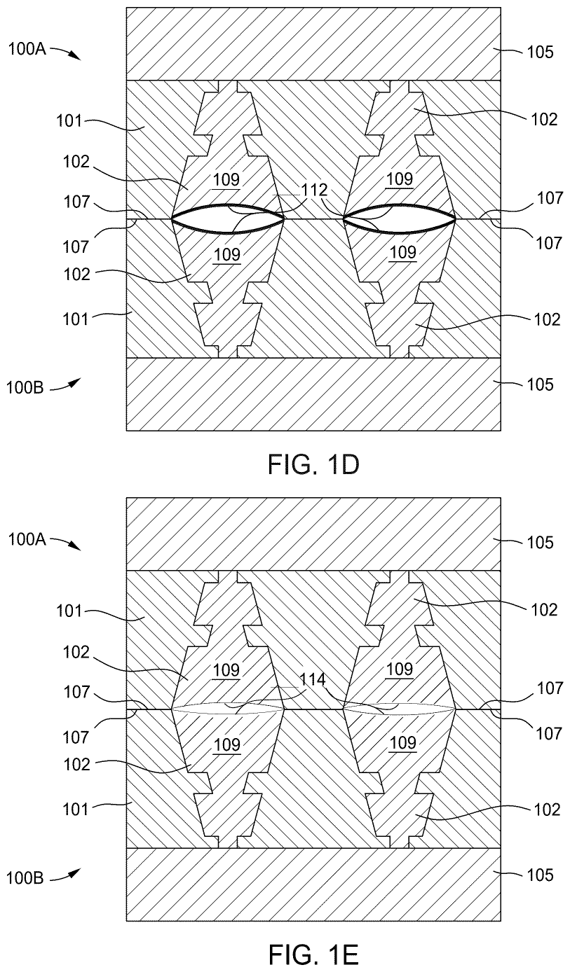

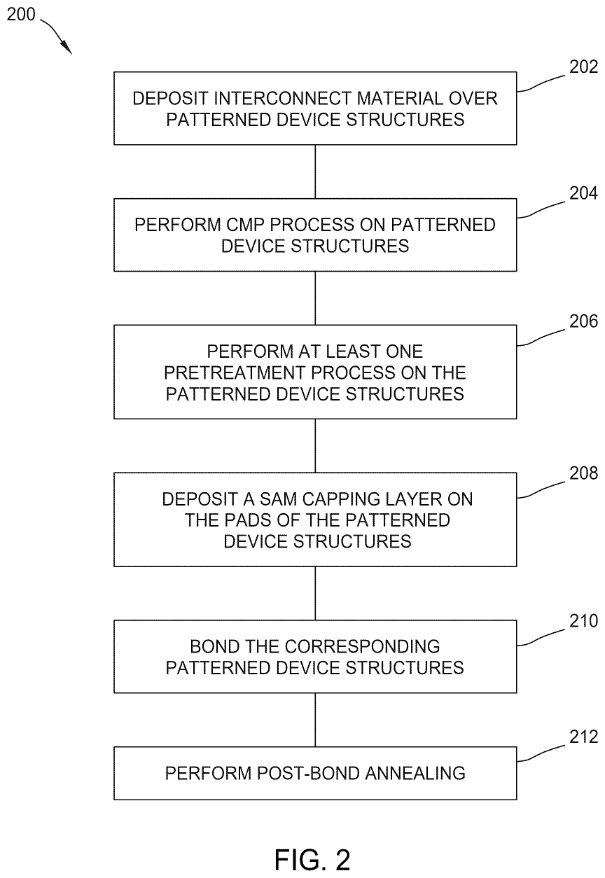

FIGS. 1A-1E illustrate schematic diagrams of a packaged device during bonding according to one or more embodiments. FIG. 2 illustrates operations for a method 200 for hybrid bonding according to one or more embodiments.

At operation 202, an interconnect material is deposited over patterned device structures. For example, as shown in FIG. 1A, a patterned device structure 100A includes a dielectric layer 101 formed over a die 105. In one or more embodiments, the patterned device structure 100A is one of numerous patterned device structures (dies or chips) formed across a base substrate (i.e., “a substrate”). In one embodiment, the numerous patterned device structures (also referred to as “dies”) are formed across the substrate in a grid-like fashion. In one embodiment, the operations described herein are performed on each patterned device structure formed on the substrate. The substrate includes multiple layers of metal wiring in insulating dielectrics that are commonly referred to as the Back-End-of-Line (BEOL) layers. The dielectric layer 101 may comprise an inorganic dielectric material layer such as oxide, nitride, oxynitride, oxycarbide, carbides, carbonitrides, diamond, diamond like materials, glasses, ceramics, glass-ceramics, and the like. In one or more embodiments, the dielectric layer 101 is a layer deposited specifically for hybrid bonding and/or is the last of the BEOL layers.

In one embodiment, interconnect structures 102 are embedded (i.e., are etched) in the dielectric layer 101. In one embodiment, the interconnect structures 102 are positioned such that the interconnect structures 102 can be mated during bonding to form continuous conductive interconnects. The interconnect structures 102 may be formed using any suitable etching process such as a damascene etching process.

As noted above, an interconnect material 103 is deposited over the patterned device structure 100A. In one embodiment, the interconnect material 103 covers the dielectric layer 101 and fills the interconnect structures 102. In one or more embodiments, the interconnect material 103 is a conductive material. The interconnect material 103 may comprise any suitable conductive material such as copper (Cu). In at least one embodiment, the interconnect material 103 is a copper barrier seed layer (CuBS).

At operation 204, a chemical mechanical polishing (CMP) process is performed on each of the patterned device structures. For example, as shown in FIG. 1B, the patterned device structure 100A undergoes a CMP process. In one or more embodiments, the CMP process is performed on the interconnect material 103. The CMP process removes the interconnect material 103 from a field region 107 (i.e., the unetched portions) of the dielectric layer 101, leaving interconnect regions such as pads 109 formed within interconnect structures 102.

Performing the CMP process includes polishing the field region 107 of the dielectric layer 101 to meet dielectric roughness specifications. As shown in FIG. 1B, the CMP process removes the portions of the interconnect material 103 formed on the field region 107 of the dielectric layer 101 and exposes pads 109 in the interconnect structures 102. The pads 109 are configured to bond with corresponding pads of corresponding patterned interconnect structures formed on the same substrate or a different substrate to form bonded interconnect structures. The pads 109 are exposed through openings etched in the dielectric layer 101. In one embodiment, the CMP process is performed in a CMP processing system. In one or more embodiments, the CMP process is used for “dishing” control onto the pads 109. In one or more embodiments, the CMP process is configured to include from about 3 nm of dishing to about 1 nm of protrusion. In one or more embodiments, the CMP process is performed until the pads 109 include a desired amount of protrusion. The desired amount of protrusion may be from about 0 to about 1 nm. In another embodiment, the CMP process is performed until the pads 109 include a desired amount of dishing. The desired amount of dishing may be from about-3 nm to about 0 nm, such as about-3 nm to about 0.1 nm.

After the CMP processes, the substrate, and therefore, the patterned device structure 100A, is cleaned and removed from the CMP processing tool and is stored and/or moved to a subsequent tool to undergo additional processing. When the patterned device structure 100A is transported between tools (or stored), the patterned device structure 100A is exposed to atmosphere. The exposure to atmosphere, problematically, as shown in FIG. 1B, may cause a contaminant, such as an oxidation layer 111 to form on a top surface of the pads 109. The oxidation layer 111 may be removed by performing at least one pre-treatment process.

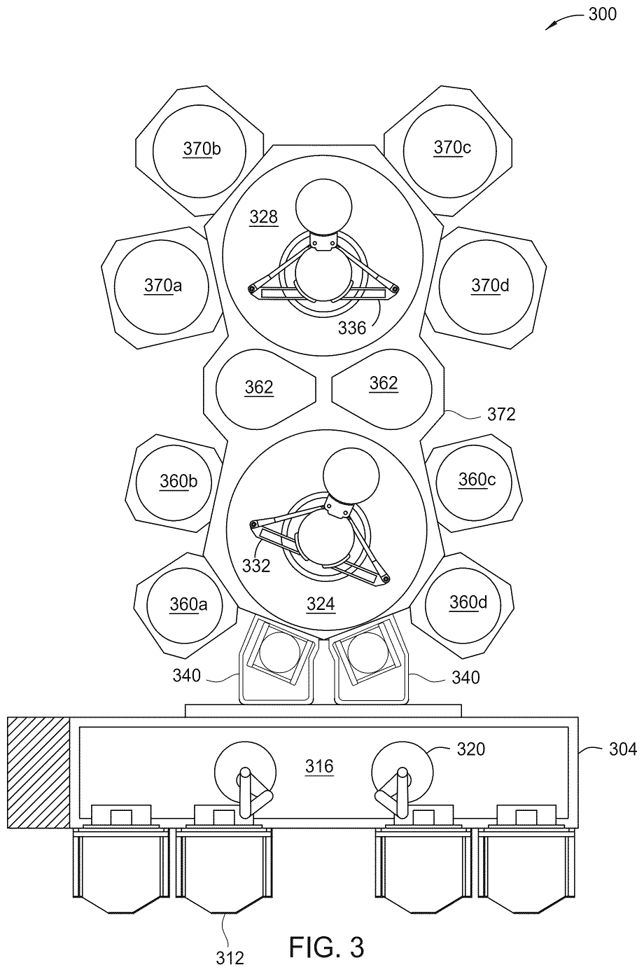

At operation 206, at least one pretreatment process is performed on the patterned device structures (e.g., patterned device structure 100A) to remove a contaminant, such as the oxidation layer 111 and expose the surface of the pads. In some embodiments, the at least one pretreatment process includes a pre-cleaning process performed in an integrated cluster tool, such as the cluster tool 300, depicted in FIG. 3.

In one or more embodiments, the at least one pre-cleaning process includes a plasma treatment process. In at least some embodiments, the pre-cleaning process may be performed by supplying a pre-cleaning gas mixture including a hydrogen containing etchant. The pre-cleaning gas mixture includes at least a hydrogen containing gas. While supplying the hydrogen containing gas in the pre-cleaning gas mixture, an inert gas may also be optionally supplied during the pre-cleaning process. Suitable examples of the hydrogen containing gas include H₂, H₂O, H₂O₂, and the like. Suitable examples of the inert gas may also be supplied into the pre-cleaning gas mixture as needed. Examples of the inert gas supplied in the gas mixture include Ar, He, Ne, Kr, Xe and the like. In at least one embodiment, the pre-cleaning gas mixture includes H₂.

In some embodiments, which can be combined with other embodiments, a remote plasma power is applied to form a plasma from the pre-cleaning gas mixture. The pads of the patterned device structure are exposed to the generated plasma. The plasma generated remotely during the pre-cleaning process may have the etchants dissociated to form relatively mild and gentle etchants, so as to slowly, gently and gradually etch the surface contaminants to expose the surface of the pads. The remote plasma process provides good control for the interface cleaning and promotes high etching selectivity while minimizing re-sputter of metal oxide onto the field region 107 of the dielectric layer 101, and potential damage to the dielectric layer 101. In at least one embodiment, the plasma generated is a non-ionizing H₂ plasma.

In at least one embodiment, which can be combined with other embodiments, the at least one pretreatment process includes, flowing H₂ into a processing chamber at a flow rate of about 200 sccm to about 2,000 sccm. A carrying gas may optionally be supplied into the processing chamber at a ratio of H₂ to carrier gas of about 5:95 to about 99.8:0.2. In at least one embodiment, He is used as the carrying gas and the He is supplied into the processing chamber at a H₂:He ratio of 5:95. In at least one embodiment, water (H₂O) is used in place of the carrying gas and the H₂O is supplied into the processing chamber at a H₂:H₂O ratio of 99.6:0.4. The processing chamber is operated at a temperature of about 25° C. to about 350° C., a pressure of about 1E-7 Torr to about 5E-7 Torr, such as about 3E-7 Torr, and a radio-frequency (RF) power of about 200 W to about 1,000 W for about 60 seconds to about 300 seconds.

At operation 208, a self-assembled monolayer (SAM) layer deposition process is performed on the patterned device structures. In at least some embodiments, a SAM capping layer 112 is selectively deposited over the exposed surface of the pads 109, forming a cap or capping layer. For example, as illustrated in FIG. 1C, a SAM capping layer 112 is deposited over a top surface of the pads 109. The SAM capping layer 112 is highly selective to the interconnect material 103 forming the pads 109. In at least one embodiment, the SAM capping layer is highly selective to copper. In at least some embodiments, the SAM capping layer 112 poison the pads 109 and prevent metal oxide formation. Thus, once the SAM capping layer is deposited the patterned device structures may be exposed to and stored in atmosphere without forming an oxide layer on the pads 109.

As used herein, “self-assembled monolayer” (“SAM”) generally refers to a layer of molecules that are attached (e.g., by a chemical bond) to a surface and that have adopted a preferred orientation with respect to that surface and even with respect to each other. The SAM typically comprises an organized layer of amphiphilic molecules in which one end of the molecule, the “head group” shows a specific, reversible affinity for a substrate. Selection of the head group will depend on the application of the SAM, with the type of SAM compounds based on the substrate utilized. Generally, the head group is connected to an alkyl chain in which a tail or “terminal end” can be functionalized, for example, to vary wetting and interfacial properties. Self-assembled monolayers have been shown, with sufficient time, to cover surfaces so completely that the properties of that surface are changed. The molecules that form the SAM will selectively attach to one material over another material (e.g., copper vs. dielectric) and if of sufficient density, can successfully block subsequent oxidation.

In one or more embodiments, which can be combined with other embodiments, the SAM capping layer 112 may be a benzotriazole layer.

In one or more embodiments, the SAM capping layer 112 is deposited using a thermal ALD process comprising alternating exposure of the patterned device structure 100A to a first reactant and a second reactant. For example, the first reactant may clean and prepare the surface of the pads 109 and the second reactant may form the SAM capping layer 112. In one or more embodiments, the SAM capping layer 112 is deposited in a cluster tool such as the cluster tool 300, depicted in FIG. 3. Thus, in one or more embodiments, the cleaning process and SAM capping layer deposition process are performed in a same cluster tool without an air-break (e.g. a vacuum or inert gas containing environment without being exposed to atmosphere).

In some embodiments, the first reactant may include any suitable reactant for reducing the interconnect material 103 forming the pads 109. In at least one embodiment, the first reactant includes a plurality of reactants, such as N₂ and ethanol (EtOH). In some embodiments, the second reactant may include any suitable reactant for forming the SAM capping layer 112, such as triazole compounds, benzotriazole, benzotriazole derivatives and the like. In some embodiments, the second reactant includes benzotriazole.

In some embodiments, the patterned device structure 100A is heated prior to deposition of the SAM capping layer 112. In at least one embodiment, the patterned device structure 100A is heated to a temperature within a range of about 95° C. to about 105° C., such as from about 97° C. to about 102° C., or about 100° C. During deposition of the SAM capping layer 112, the processing chamber may be heated to a temperature within a range of about 95° C. to about 300° C., such as from about 100° C. and about 300° C.

In some embodiments, which can be combined with other embodiments, the first reactant for the SAM capping layer 112 may be flowed or pulsed into the processing chamber while operating the processing chamber at a temperature of about 300° C. The word “pulse” used herein is intended to refer to a quantity of a particular compound that is intermittently or non-continuously introduced into a reaction zone of a processing chamber.

After flowing the first reactant into the processing chamber, a first purge process may optionally be performed to remove any residual first reactant in the processing chamber. The first purge process may include pulsing a purge gas, such as Ar or N₂ gas, into the processing chamber.

In some embodiments, which can be combined with other embodiments, the second reactant, such as benzotriazole, is then flowed or pulsed into the processing chamber. The processing chamber is operated at a pressure of about 40 mTorr to about 70 mTorr, such as about 40 mTorr to about 60 mTorr, or about 50 mTorr, and a temperature of about 95° C. to about 105° C., such as about 100° C. for a duration of about 100 seconds to about 400 seconds, such as about 200 seconds to about 300 seconds. In some embodiments, a monolayer of the second reactant may be formed on the patterned device structure 100A. In some embodiments, the second reactant is introduced into the processing chamber with a carrier gas, such as an inert gas like N₂, Ar, He, Ne, Kr, Xe and the like.

A second purge process may be performed following the pulsing of the second reactant. The second purge process may be performed to remove any residual second reactant in the processing chamber. Similar to the first purge process, the second purge process may include pulsing a purge gas, such as Ar or N₂, into the processing chamber.

The pulsing of the first reactant and the second reactant into the processing chamber may be a cycle, and the cycle may include the first and second purge processes after flowing the first reactant into the processing chamber and after flowing the second reactant into the processing chamber. In some embodiments, the cycle may include one purge process after flowing the second reactant into the processing chamber. The cycle is repeated to grow the SAM capping layer 112. The number of cycles is based on the desired thickness of the final SAM capping layer 112. The growth rate of the SAM capping layer 112 may range from about 0.5 nm to about 4 nm per cycle, such as about 1 nm to about 3 nm, about 1.5 nm to about 2.5 nm, or about 2 nm to about 2.5 nm. A final thickness of the SAM capping layer may be any suitable thickness to effectively prevent the formation of metal oxide on the exposed surface of the pads 109. In at least one embodiment, the SAM capping layer 112 is a monolayer. In other embodiments, the SAM capping layer 112 is any number of stacked monolayers required to reach the desired thickness.

At operation 210, as shown in FIG. 1D the corresponding patterned device structures are bonded to each other. In one or more embodiments, patterned device structure 100A is bonded to a patterned device structure 100B (i.e., source and target dies) that are identical to each other. In one embodiment, bonding corresponding patterned device structures includes, but is not limited to, loading the substrate into dedicated bonding tool. In one embodiment, the dedicated bonding tool, aligns the patterned device structures (i.e., the dies), cleans the patterned device structures, performs a degassing process on the patterned device structures, performs a plasma activation process on the patterned device structures, treats the patterned device structures with ultraviolet (UV) light, and bonds the source and target patterned device structures to one another. Although FIG. 1D illustrates a single die stack (i.e., one patterned device structure stacked on top of another), this is for exemplary purposes only, as multiple die stacks may be formed.

For example, as illustrated in FIG. 1D, the patterned device structure 100A is flipped, aligned, and then bonded to the patterned device structure 100B. The patterned device structures are bonded in a manner such that the SAM capping layer 112 formed on the pads 109 and the field region 107 (i.e., the unetched regions) of the dielectric layer 101 are aligned with one another.

In one or more embodiments, in the plasma activation process, each of the patterned device structures is exposed to a plasma, which bombards the surface of each patterned device structure (e.g., patterned device structure 100A and 100B). The interaction between the plasma and the surface of the patterned device structures exposes the surface 114 of the pads 109, and creates reactive sites that increase surface energy and wettability, promoting better adhesion and bonding quality in the hybrid bonding process.

In one or more embodiments, an O₂ or an N₂ activation plasma is used to activate the dielectric layer 101 and remove the SAM capping layer 112. In at least one embodiment, the formed SAM layer is configured (e.g., material, thickness, etc.) so that the time required to remove the SAM capping layer 112 is equal to, or is approaching equal to, the time required to perform the dielectric activation process, thus allowing the activation and removal of the SAM capping layer 112 to be performed in a single step. In other embodiments, the dielectric activation and removal of the SAM capping layer 112 are performed as a two-step process. The SAM capping layer 112 is removed with a first activation plasma, then the dielectric and exposed pads are activated with a second activation plasma. The first and second activation plasmas may be the same or different. In at least one embodiment the SAM capping layer 112 is removed using an O₂ activation plasma and the dielectric and exposed pads are activated with a N₂ activation plasma. Activating the dielectric and exposed pads after the removal of the SAM capping layer 112 with an N₂ activation plasma prevents undesired oxidation of the pads exposed surface 114.

At operation 212, a post-bonding annealing process is performed on the bonded patterned device structure (i.e., patterned device structure 100A bonded to patterned device structure 100B). In one or more embodiments, the post-bonding annealing process causes the pads 109 of the opposing patterned device structures to undergo thermal expansion, contact one another, and then diffuse into one another. As illustrated in FIG. 1E, the patterned device structures 100A and 100B are exposed to heat for a duration of time from about 1 minute to about 600 minutes. The annealing processes causes thermal expansion of the pads 109, which causes the opposing pads 109 to contact, which then causes the metal diffusion of the opposing pads of the aligned patterned device structures 100A and 100B. Advantageously, due to the SAM capping layer 112 preventing the formation of metal oxide, the annealing temperature may be from about 180° C. to about 350° C., such as less than 300° C. The SAM capping layer 112 allows for a lower anneal temperature than typical post-bond annealing processes which is from about 350° C. to about 400° C. The lower anneal temperature reduces the thermal budget of the post-bond annealing process and reduces stress build up during the post-bond annealing, especially for memory devices with a lower thermal budget or devices that include multi-die stacking which may include multiple bonding and post-bonding annealing processes.

FIG. 3 is a schematic plan view of a cluster tool 300. One example of the cluster tool 300 is the Endura® system from Applied Materials, Inc. of Santa Clara, California. It is understood that the cluster tool 300 described below is an exemplary cluster tool and other cluster tools, including those from other manufacturers, may be used with or modified to form SAM capping layers as described herein.

The cluster tool 300 includes a factory interface 304, loading dock 340, first transfer chamber 324, and second transfer chamber 328. A plurality of cassettes 312, or front opening unified pods (“FOUPs”), are disposed on the factory interface 304 and are configured to receive a plurality of patterned device structures (shown in FIG. 1 as 100A) for processing, such as, for example, performing operations 206 and 208. Prior to processing, the patterned device structures 100A are removed from the cassettes 312 by factory interface robots 320 and are transferred to the loading dock 340 (i.e., load lock). Upon completion of substrate processing in the cluster tool 300, the processed patterned device structures 100A may be returned to their respective cassettes 312.

The first transfer chamber 324 is part of a main frame 372 and houses a centrally disposed first transfer robot 332. The first transfer robot 332 is configured to move the patterned device structures 100A between the loading dock 340 and a plurality of first processing chambers 360 (360a-d are shown in FIG. 3) and/or pass-through chambers 362. The first transfer chamber 324 can be selectively isolated from each of the first processing chambers 360 and pass-through chambers 362 by use of slit valves (not shown) that are disposed between each first processing chamber 360 and pass-through chamber 362 and the first transfer chamber 324.

Each loading dock 340 is selectively isolated from the first transfer chamber 324 by slit valves and from the interior region 316 of the factory interface 304 by vacuum doors (not shown). In this configuration, the factory interface robots 320 in the factory interface 304 are configured to move a patterned device structure 100A from a cassette 312 to the loading dock 340, which may be sealed and pumped down to a desired pressure for transfer of the patterned device structure 100A to the first transfer chamber 324. Upon reaching a desired pressure, the patterned device structure 100A can then be accessed by the first transfer robot 332 through a slit valve opening (not shown) formed between the first transfer chamber 324 and the loading dock 340.

The first processing chambers 360 may include any suitable type of processing chambers for removing the oxide layer 111 from the patterned device structures 100A. In some embodiments, the first processing chambers 360 include one or more pre-clean chambers that are adapted to clean the surfaces of the patterned device structures 100A. The pre-clean chambers may clean the surfaces of the patterned device structures 100A by use of a cleaning process that includes exposing the surfaces of the patterned device structures 100A to a radio frequency (RF) generated plasma and/or one or more pre-cleaning gas compositions that includes a carrier gas (e.g., Ar, He, Kr) and/or a reactive gas (e.g., hydrogen). In some embodiments, the pre-clean chambers are adapted to perform a non-ionizing H₂ plasma pre-clean process that may minimize metal oxide re-sputter onto the dielectric layer 101 and minimizes damage to the dielectric layer 101.

The first transfer chamber 324 and the second transfer chamber 328 are coupled to each other via the pass-through chambers 362. In some configurations, the first transfer chamber 324 may be vacuum pumped to a moderately low pressure, for example, less than about 1 milliTorr (mTorr). The second transfer chamber 328 may be pumped to a lower pressure, for example, 1 microTorr or less. Accordingly, the first and second transfer chambers 324, 328 are maintained at least at a moderate vacuum level to prevent the transfer of contamination between the transfer chambers 324, 328 and other modules of the cluster tool 300.

Similar to the first transfer chamber 324, the second transfer chamber 328 is part of the main frame 372 and houses a centrally disposed second transfer robot 336. The second transfer robot 336 is configured to move the patterned device structures 100A between each of a plurality of second processing chambers 370 and/or the pass-through chambers 362. The second transfer chamber 328 can be selectively isolated from each of the second processing chambers 370 and the pass-through chambers 362 by use of slit valves (not shown) that are disposed between each second processing chamber 370 and pass-through chamber 362 and the second transfer chamber 328. In certain embodiments, one or more of the second processing chambers 370 are ALD chambers configured to deposit SAM capping layers as described herein.

Over all, the present disclosure provides a system and methods for forming a SAM capping layer on pads to prevent oxidation during bonding. Methods disclosed herein generally include a sequential pre-cleaning step to remove metal oxide and an ALD step to deposit the SAM capping layer, that are performed without an air-break. The SAM capping layer prevents oxidation of the pads while the patterned device structure is transported between tools (or stored), and are removed during a pre-bonding plasma activation. Due to the SAM capping layer 112 preventing the formation of metal oxide, the annealing temperature may be from about 180° C. to about 350° C.

While the foregoing is directed to implementations of the present disclosure, other and further implementations of the disclosure may be devised without departing from the basic scope thereof. The present disclosure also contemplates that one or more aspects of the implementations described herein may be substituted in for one or more of the other aspects described. The scope of the disclosure is determined by the claims that follow.

Certain implementations and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method, comprising:
providing patterned device structures comprising a dielectric layer disposed over a substrate, the dielectric layer including a plurality of interconnect structures etched therein, an interconnect material disposed within the plurality of interconnect structures forming a plurality of pads within the plurality of interconnect structures of the patterned device structures;
removing a contaminant from the patterned device structures using a plasma treatment process to expose a surface of the pads within the interconnect structures of the patterned device structures; and
selectively depositing a self-assembled monolayer (SAM) capping layer on the surface of the pads within the interconnect structures of the patterned device structures.

2. The method of claim 1, further comprising bonding corresponding patterned device structures to each other.

3. The method of claim 2, wherein bonding the corresponding patterned device structures further comprises a plasma activation process comprising:
exposing the corresponding patterned device structures to an activation plasma comprising O₂ or N₂;
removing the SAM capping layer from the pads; and
activating the dielectric layer of the patterned devices.

4. The method of claim 3, wherein the SAM capping layer is removed and the dielectric layer is activated in a single step.

5. The method of claim 3, wherein the activation plasma comprises N₂.

6. The method of claim 1, wherein the SAM capping layer comprises benzotriazole.

7. The method of claim 1, wherein selectively depositing the SAM capping layer comprises flowing benzotriazole into a processing chamber and operating the processing chamber at a pressure of about 40 m Torr to about 70 mTorr and a temperature of about 95° C. to about 105° C. for a duration of about 100 seconds to about 400 seconds.

8. The method of claim 1, wherein the interconnect material is copper.

9. The method of claim 1, wherein the SAM capping layer is highly selective to copper.

10. The method of claim 1, wherein removing the layer of metal oxide and selectively depositing the SAM capping layer are both performed in a cluster tool with no air break between the removing and depositing steps.

11. The method of claim 1, wherein the plasma treatment process comprises a non-ionizing H₂ plasma.

12. A patterned device structure comprising:
a dielectric layer disposed over a substrate, the dielectric layer including a plurality of interconnect structures etched therein;
an interconnect material disposed within the plurality of interconnect structures forming a plurality of pads within the plurality of interconnect structures; and
a self-assembled monolayer (SAM) capping layer disposed on at least one pad of the plurality of pads.

13. The patterned device of claim 12, wherein the SAM capping layer comprises benzotriazole.

14. The patterned device of claim 13, wherein the SAM capping layer has a thickness of about 2.5 nm.

15. The patterned device of claim 12, wherein the interconnect material is copper.

16. The patterned device of claim 12, wherein the SAM capping layer is highly selective to copper.

17. A method, comprising:
providing two or more patterned device structures comprising an interconnect material disposed over a dielectric layer disposed over a substrate, the dielectric layer including a plurality of interconnect structures etched therein, wherein the interconnect material fills the plurality of interconnect structures, and is disposed over the plurality of interconnect structures and a field region of the dielectric layer;
performing a chemical mechanical polishing (CMP) process to remove portions of the interconnect material disposed on the field region of the dielectric layer and expos a plurality of pads within the plurality of interconnect structures of the two or more patterned device structures;
exposing the plurality of pads of the two or more patterned device structures to atmosphere;
exposing the plurality of pads to a plasma treatment process;
selectively depositing a self-assembled monolayer (SAM) capping layer on the exposed plurality of pads within the interconnect structures of the two or more patterned device structures after exposing the plurality of pads to a plasma treatment process;
bonding corresponding patterned device structures of the two or more patterned device structures to each other; and
annealing the bonded corresponding patterned device structures.

18. The method of claim 17, wherein bonding the corresponding patterned device structures further comprises a plasma activation process comprising:
exposing the corresponding patterned device structures to an activation plasma comprising O₂ or N₂;
removing the SAM capping layer from the pads; and
activating the dielectric layer of the patterned devices.

19. The method of claim 17, wherein the SAM capping layer is deposited using an atomic layer deposition process and comprises benzotriazole.

20. The method of claim 17, wherein the annealing process is performed at an annealing temperature of 300° C. or less.
